(19) United States
(12) Patent Application Publication
(10) Pub. No.: US 2026/0058580 A1
(43) Pub. Date: Feb. 26, 2026

(54) CYMBAL MICROMEMBRANE-BASED ENERGY HARVESTING IN ACOUSTIC METASURFACES

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/814,055

(22) Filed: Aug. 23, 2024

(51) Int. Cl. H02N 2/18; H10N 30/30

(52) U.S. Cl. CPC H02N 2/188; H02N 2/181; H02N 2/185; H10N 30/308

(57) ABSTRACT

The technology described herein is directed towards resonators that incorporate or are closely coupled to transducers from which energy is harvested. The resonators can be unit cells of a metasurface configured for narrowband sound absorption by phase cancellation of the acoustic wave. Membrane-based transducers such as cymbal harvester transducers can be positioned, e.g., at the neck ports of the resonators, to generate electricity as the air pressure of incoming acoustic waves enters the unit cells. Energy can be harvested from the electricity, and stored for usage and/or used directly to power a device. Such a device powered by the harvested energy can change the resonant frequency of the device, e.g., by changing temperatures in the resonators' air cavities, changing respective dimensions of the respective air cavities, or changing the resonant frequency of the unit cells resonators by changing respective airflow in the respective air cavities.

### RELATED APPLICATION

The subject patent application is related to U.S. patent application Ser. No. ______, filed ______, and entitled “ENERGY HARVESTING ACOUSTIC METASURFACE USING PIEZOELECTRIC TRANSDUCERS” (docket no. 139391.01/DELLP1282US), the entirety of which patent application is hereby incorporated by reference herein.

### BACKGROUND

Acoustic absorbers are specialized materials or structures designed to mitigate the effects of sound reflections, echoes, and reverberations in various environments. These absorbers function by capturing sound waves and converting their energy into heat, effectively reducing the intensity of the sound waves and preventing them from bouncing off surfaces and causing unwanted sound reflections. They are typically engineered using porous materials with intricate structures that allow sound waves to penetrate deep into the material, where the acoustic energy is dissipated as thermal energy through friction and air resistance.

Existing acoustic absorbers come in various forms, including foam panels, fabric-wrapped panels, diffusers, bass traps, and more. One of the problems with existing acoustic absorbers is that they are not desirable in certain heat-sensitive environments. For example, servers generate a lot of heat and thus are designed with fans to cool dissipate the heat; however, fans can generate a lot of annoying noise. Using existing acoustic absorbers to absorb server noise reduces the noise, but can significantly reduce dissipation of the heat generated by servers, which can result in high heat levels that can reduce server performance and possibly cause a server to shut down to avoid damage from overheating.

### BRIEF DESCRIPTION OF THE DRAWINGS

The technology described herein is illustrated by way of example and not limited in the accompanying figures in which like reference numerals indicate similar elements and in which:

FIG. 1 is a block diagram showing an example system in which a Helmholtz resonator includes piezoelectric transducers in a neck port of the resonator for generating electricity based on acoustic energy resonating the resonator, in accordance with various example embodiments and implementations of the subject disclosure.

FIG. 2 is a block diagram showing an example system in which a Helmholtz resonator includes cymbal harvester transducers coupled to the neck port of the resonator for generating electricity based on acoustic energy oscillating a membrane of the cymbal harvester transducer in accordance with various example embodiments and implementations of the subject disclosure.

FIG. 3A is a two-dimensional side view representation of example unit cell resonators, including one enlarged unit cell showing various dimensions that determine, in part, the unit cell's resonance frequency, in accordance with various example embodiments and implementations of the subject disclosure.

FIG. 3B is a graphical representation of resulting absorption coefficient values of the unit-cell(s) of FIG. 3A over a range of frequencies, including a very high absorption coefficient value at the designed frequency 1310 Hz, in accordance with various example embodiments and implementations of the subject disclosure.

FIG. 4 is a side view representation of example unit cell resonators (e.g., of an acoustic metasurface) in which piezoelectric and/or cymbal harvester transducers output energy that can be combined for storage or direct usage, in accordance with various example embodiments and implementations of the subject disclosure.

FIG. 5 is a side view representation of an example Helmholtz resonator that includes multiple heating elements, powered by harvested energy from transducers, for varying the resonator's resonance frequency by changing the air temperature in the resonator's chamber, in accordance with various example embodiments and implementations of the subject disclosure.

FIG. 6 is a side view representation of an example noise canceling Helmholtz resonator that includes heaters, powered by harvested energy from transducers, for varying the resonance frequency by changing air temperature in the resonator's chamber based on sensor feedback to a controller, in accordance with various example embodiments and implementations of the subject disclosure.

FIG. 7 is a side view representation of an example noise canceling Helmholtz resonator that includes a MEMS actuator (e.g., a bimorph actuator), powered by harvested energy from transducers, for varying the resonance frequency by changing the airflow in the resonator's chamber by moving a moveable part within the resonator's chamber, in accordance with various example embodiments and implementations of the subject disclosure.

FIG. 8 is a side view representation of an example noise canceling Helmholtz resonator that includes a MEMS actuator, powered by harvested energy from transducers, for varying the resonance frequency by changing the volume of the resonator's chamber by moving a moveable part within the resonator's chamber, in accordance with various example embodiments and implementations of the subject disclosure.

FIG. 9 is a side view representation of an example noise canceling Helmholtz resonator that is coupled to an external actuator, powered by harvested energy from transducers, for varying the resonance frequency by changing the volume of the resonator's chamber by moving a moveable part within the resonator's chamber, in accordance with various example embodiments and implementations of the subject disclosure.

FIG. 10 is a side view representation of example noise canceling Helmholtz in which a shared actuator, powered by harvested energy from transducers, collectively varies the resonance frequency of unit cell resonators by moving a shared moveable sheet with respective protrusions that act as respective moveable floors of their respective resonators' chambers, in accordance with various example embodiments and implementations of the subject disclosure.

FIG. 11 is a three-dimensional, perspective representation of an example sound absorbing metasurface composed of unit cells for wrapping around a rack of servers to reduce noise emanating from the servers, while producing power via transducers, in accordance with various example embodiments and implementations of the subject disclosure.

### DETAILED DESCRIPTION

Various embodiments and implementations of the technology described herein are generally directed towards Helmholtz resonators (e.g., for unit cells of a metasurface) with transducers that output electricity based on airflow/air pressure in the resonators, for energy harvesting. In one implementation, the transducers are electroacoustic transducers such as piezoelectric transducers. In another implementation, the transducers are cymbal harvester transducers; both types of transducers can be combined in a system, including using both types in the same resonator.

A cymbal harvester transducer located proximate to the neck of the resonator harvests energy from the constant acoustic pressure going through the metasurface. With the change in the acoustic pressure of the incoming air, such as noise, the cymbal harvester transducer generates electric current. The placement or the position of the transducer can be chosen such that at the energy dense (high-pressure) area, a higher conversion efficiency can be achieved.

This approach if combined with integrating flexible heaters inside the cavity, the energy generated from the cymbal harvester transducer can directly be applied to drive the heating mechanism or linear motor mechanism thus reducing the overall impact of the energy usable of the metasurface. Other variable resonance devices can be used that are powered by the harvested energy.

The resonators can be unit cells of a sound absorbing acoustic metasurface that cancels one or more frequencies based on inverted phase cancellation. A metasurface panel may have a lot of unit cells, and collectively, some or all of the cells, working together, can generate sufficient energy to power unit cell reconfigurability (reconfiguration) solutions. In addition to (or instead of) storing the harvested energy, the harvested energy can be used to vary the resonance frequency of resonators, and more particularly to power a resonant frequency reconfiguration device. Nonlimiting examples of such resonant frequency reconfiguration devices include heaters that vary temperatures within the resonators and thus vary the resonance frequency of the resonators, actuators that vary the volumes of the resonators and thus vary the resonance frequency of the resonators, and/or actuators that vary the airflow within in the resonators and thus vary the resonance frequency of the resonators.

Reference throughout this specification to “one embodiment,” “an embodiment,” “one implementation,” “an implementation,” etc. means that a particular feature, structure, or characteristic described in connection with the embodiment/implementation is included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, or characteristics may be combined in any suitable manner in one or more embodiments/implementations. It also should be noted that terms used herein, such as “optimize,” “optimization,” “optimal,” “optimally” and the like only represent objectives to move towards a more optimal state, rather than necessarily obtaining ideal results. For example, “optimal” placement of a subnet means selecting a more optimal subnet over another option, rather than necessarily achieving an optimal result. Similarly, “maximize” means moving towards a maximal state (e.g., up to some processing capacity limit), not necessarily achieving such a state.

Further, it is to be understood that the present disclosure will be described in terms of a given illustrative architecture; however, other architectures, structures, substrate materials and process features, and steps can be varied within the scope of the present disclosure.

It will also be understood that when an element such as a layer, region or substrate is referred to as being “on” or “over” another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

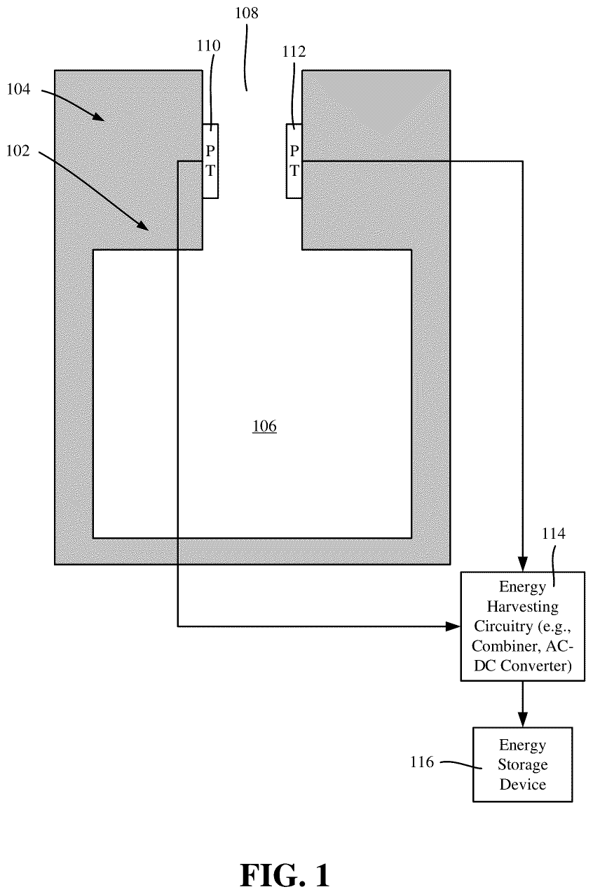

FIG. 1 is a block diagram of an example system 100 that includes an air cavity-type resonator (unit cell) 102 supported by a surrounding structure 104. In this example, the unit cell resonator is a Helmholtz resonator having a chamber 106 and a neck port 108 that exposes the chamber 108 to incoming acoustic waves. One or more piezoelectric transducers (in this example two piezoelectric transducers PT 110 and 112) are positioned in the neck port 108, and as the air of incoming acoustic waves pass through the neck port 108, the piezoelectric transducers 110 and 112 convert the changing air pressure of the incoming acoustic waves to electricity.

Energy harvesting circuitry 114 is coupled to the transducers' output to obtain the generated electricity (current), and, for example, to convert the energy to DC current for storing in an energy storage device 116 such as a battery or capacitor. The energy harvesting circuitry 114 can also be configured to combine the electrical output of multiple transducers. Note that an energy storage device 116 may not be needed in some applications if the electricity/the harvested energy can be used directly by a power consuming device.

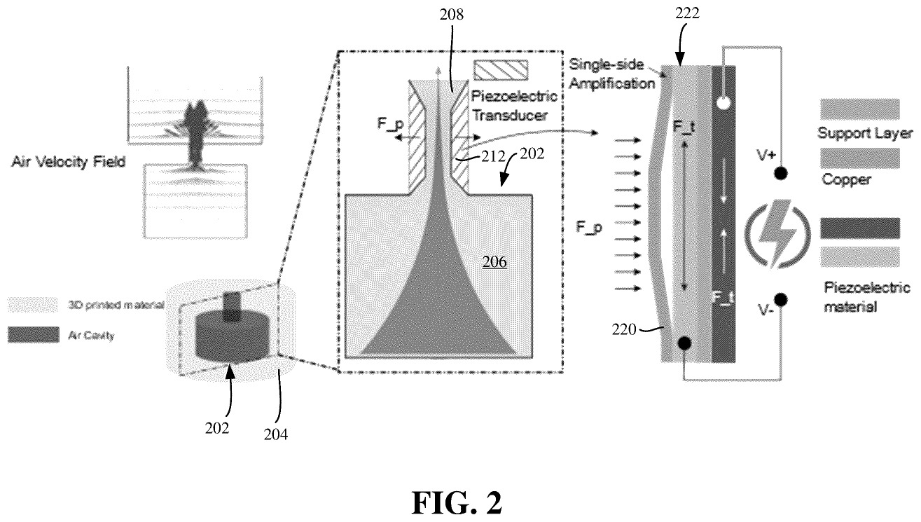

FIG. 2 shows a similar solution to harvest energy from the constant acoustic pressure encountered by a metasurface, in which at least one mechanical cymbal type membrane or “cymbal harvester transducer” is deployed with a resonator 202, such as connected near the neck 208 of the resonator 202. Instead of (or in addition to) using a piezoelectric transducer, a cymbal harvester transducer (e.g., 212) can include a thin layer of piezoelectric material coated on the structure as shown in FIG. 2. Note that “cymbal” refers to a type of structure used in mechanical energy harvesting circuits or for contact pins. A cymbal is formed from a type of flexible metal membrane, with a bump in the middle. When pressure is exerted in perpendicular direction, the membrane collapses.

As can be seen in the enlarged portion of the cymbal harvester transducer 212, a flexible metallic cymbal type membrane 220 is installed or fabricated on top of a piezoelectric layer 222. With a force exerted on the neck of the resonator via the air pressure, the cymbal membrane 220 collapses, and pushes against the piezoelectric material 222 to generate electric current. Because the shape of the flexible metallic membrane 220 has a bump, the flexible metallic membrane 220 oscillates at the resonance frequency. As a result of oscillating acoustic pressure, with the metallic membrane 220 and a piezoelectric layer 222 applied underneath. the force from acoustic pressure at resonance frequency generates electric current as shown in FIG. 2.

The unit cells are based on the principles of Helmholtz resonators, which are acoustic cavities with a small neck port or opening that are highly effective at absorbing specific frequencies via resonance. For example, the resonant frequency (f_{resonance}) of a classical Helmholtz resonator with respect to frequencies in the audible range is determined by:

$${f}_{resonance} = \frac{c}{2 π} \sqrt{\frac{S}{{L}_{p} V}}$$

where c is the speed of sound, S is the neck port cross-sectional area, Lₚ=L_{neck}+1.7r_{neck} (for a cylindrical neck port) and V is the unit cell's cavity chamber's volume.

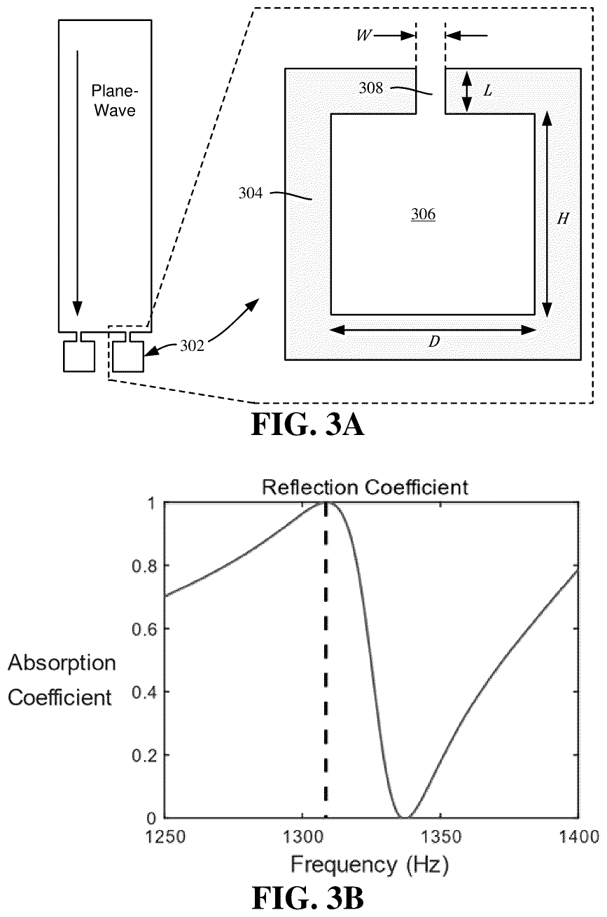

As generally represented in FIG. 3A, each unit cell 302 comprises a cavity, or air chamber 306, often with a neck port 308 that exposes the air chamber 306 to the air/incoming sound waves, with dimensions engineered to target a particular frequency or a narrowband range of frequencies of interest. The dimensions of the air chamber 306 and neck port 308 are designed based on generally desired narrow band of acoustic frequencies to cancel, allowing a metasurface of such resonating unit cells to be used as a noise cancellation device when exposed to sound waves of those frequencies. When constructed, the air chamber 306 and neck port 308, which are hollow to contain air, are enclosed in a supporting structure 304 through which the neck port 308 extends to couple the chamber to the air propagating the sound wave.

The dimensions shown in FIG. 3 include the chamber height (H), and in the example of a cylindrical air chamber, the chamber's diameter (D) which is twice the radius, such that a cylindrical air chamber's volume is:

$$V = {( π \times \frac{1}{2} D )}^{2} \times H .$$

The neck port, which is also a cylindrical tube in this example, has an area of

$${( π \times \frac{1}{2} W )}^{2}$$

and a length of L. The unit cell is not limited to cylindrical air chambers or cylindrical necks, but can be of any suitable shape that facilitates resonating at the desired frequency in a manner that phase cancels the incoming sound wave of that frequency.

The result is highly efficient sound absorption at specific frequencies as shown in FIG. 2B, which in this example is around 1310 Hz, making this metasurface particularly useful for targeted noise reduction in environments where controlling specific frequencies is beneficial, such as in architectural acoustics, automotive design, and industrial settings. The dimensions are deep subwavelength values relative to the subwavelength of the incoming wave. For example, one metasurface implementation was designed to inverse phase cancel an incoming frequency 1310 Hz, with selected unit-cell dimensions of D=18 mm, H=16 mm, L=6 mm, W=3.2 mm. The resulting absorption coefficient of the designed unit-cell achieved near-perfect (greater than 98 percent absorption at the designed frequency 1310 Hz), as shown in FIG. 2B. As can be seen from this example, the structure is deeply sub-wavelength; the wavelength λ at 1310 Hz in air is 260 mm, which is controlled by unit-cell with thickness of 22 mm. As can be seen, the above-selected dimensions of D, H, L and W for 1310 hertz (λ=260 m) in air range from about λ/14 to λ/81 (or λ/13 if based on the thickness of 22 mm). Note that while the curve of FIG. 2B shows about seventy percent absorption effectiveness around 1250 Hz increasing to the peak absorption at the desired frequency 1310 Hz, the curve can be flattened more around the designed frequency to an extent, e.g., by slightly tweaking the dimensions of some of the unit cells.

The designed unit cell only needs air and its surrounding acoustic hard boundaries, along with the energy-harvesting transducer(s). This is different from other approaches using porous and fibrous materials and gradient index materials. At this scale the unit-cell acts almost like a point towards the wave, so this design is not straightforward. However, the materials and the compact design in mm-scale/deeply sub-wavelength facilitate fabricating the unit cell as a thin, light-weight, and cost effective absorber with 3D printing technology.

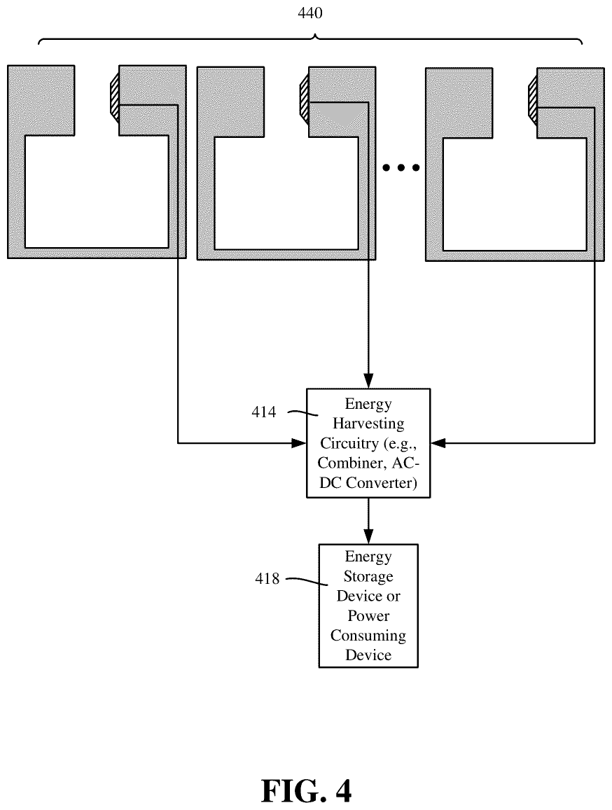

FIG. 4 is a side view representation showing how a group 440 of unit cells, such as all unit cells of an acoustic metasurface, can output electricity via transducers that can be combined via energy harvesting circuitry 414. When combined, the electricity can be stored for indirect usage thereof, and/or directly used by a power consuming device or devices, as represented by block 418 in FIG. 4. Transducers can be piezoelectric transducers, cymbal harvester transducers, or a combination of both types.

Turning to harvested energy usage scenarios, the harvested energy can be used by a device to reconfigure the resonance frequency of a resonator in a controlled manner. By way of an example acoustic metasurface usage scenario, consider a metasurface of such unit cells configured to noise cancel the fan noise emanating from a server. The Helmholtz resonators' resonant frequency can be designed to significantly cancel the noise. Later, consider that the server fan changes its frequency as the server heats up/cools down, or that the server is replaced with a different server having a different fan noise frequency. Adjusting the resonance frequency of the resonators operates to cancel the different frequency instead.

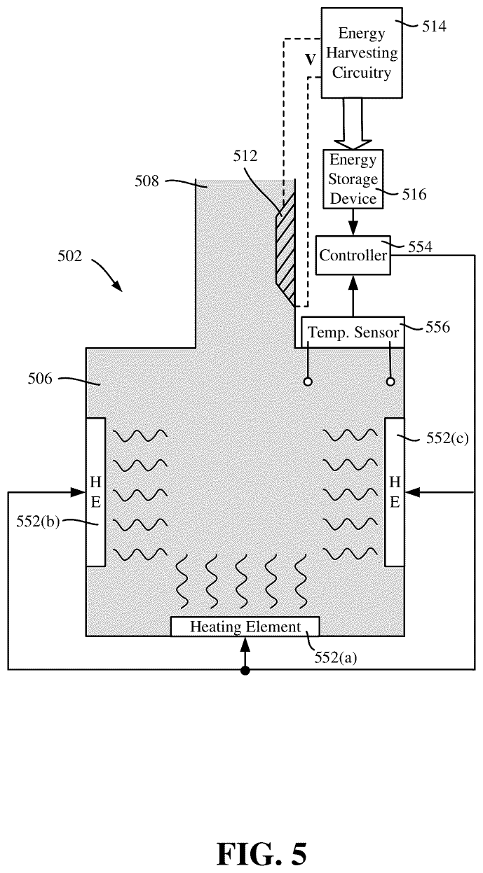

FIG. 5 shows one such resonance frequency reconfiguration device in the form of a heater, which in this example includes three heating elements 552(a)-552(c) within (or closely coupled to) the chamber 506 of the resonator 502. In the example of FIG. 5, an example Helmholtz resonator 508 with a default resonance frequency determined by dimensions of the chamber 506 and the neck port 508 as generally described herein, and in which variable resonance is based on the adjustable air temperature.

A transducer 512 is shown proximate to the neck port 508, with its electrical output coupled to energy harvesting circuitry 514. The harvested energy can be used, directly or indirectly (via an energy storage device 516 as shown) to heat the heating elements 552(a)-552(c), e.g., thin resistive material. A controller 554 can be used to controllably apply heat to the heating elements 552(ₐ)-552(_{c}), such as in an amount of heat to reach a certain temperature in the chamber 506 as sensed by a temperature sensor 556 coupled to the controller 554.

Note that the controller 554 can be coupled to control a power source (not explicitly shown in FIG. 5) to heat the heater heating elements 552(ₐ)-552(_{c}), if, for example, the controller 554 is a small microcontroller that does not output sufficient power to heat the heating elements 552(ₐ)-552(_{c}), or if multiple unit cells are collectively heated. Further note that such a heater can be positioned below the chamber rather than inside the chamber, although additional heat may be needed to transfer the heat into the chamber through the structure that supports the resonator 502.

With respect to using temperature as a variable to reconfigure the resonance frequency of the structure, the speed of sound in a specific medium can be used to achieve reconfiguration. As shown in the below equation, the speed of sound is changed by varying the medium temperature, which enables the use of electrically controlled heating elements in the unit-cell:

$${c}_{ideal} = \sqrt{γ \cdot \frac{P}{ρ}} = \sqrt{\frac{γ \cdot R \cdot T}{M}} = \sqrt{\frac{γ \cdot k \cdot T}{m}}$$

where c is the speed of sound, P is the pressure, ρ is the density, γ is the specific heat ratio, R is the gas constant, M is the molar mass, k is the Boltzmann constant and m is the mass.

The relationship between temperature of the medium and the speed of sound in the medium. Substituting this equation into the above resonance frequency equation yields the relationship utilized herein. Using a heating mechanism as described herein basically manipulates the speed term c.

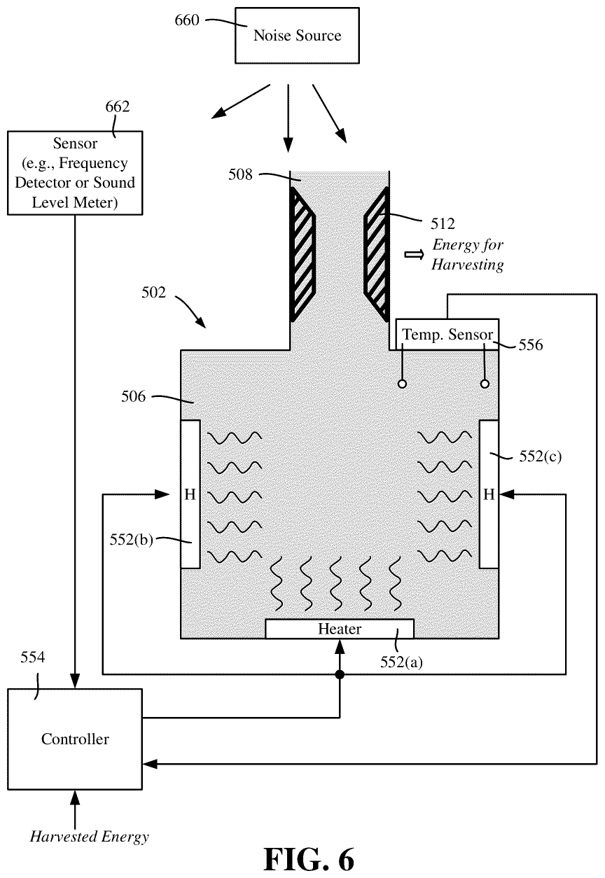

FIG. 6 shows the concept of feedback-based adjustment for noise cancellation, using the variable temperature resonator 502 of FIG. 5 as an example. In general, a noise source 660 such as one or more server fans outputs noise that can be sensed by a sensor 662. For example, a frequency sensor can pick up the main frequency peak of the noise, and communicate this information to the controller 554. The controller 554 can then calculate (or look up/interpolate from previously determined data) the actuator voltage needed to change the temperature to cancel that frequency, and adjust the heating elements 552(a)-552(c) accordingly; the temperature sensor 556 can be used in conjunction with obtaining a more precise cavity temperature. Another alternative is to sense the noise level, e.g., at some appropriate location or locations, and adjust the heating elements 552(a)-552(c) until the lowest amount of noise level results. As the frequency of the acoustic wave (noise) changes, the heaters can be adjusted to cancel the changed frequency, which can be a reasonably rapid adjustment.

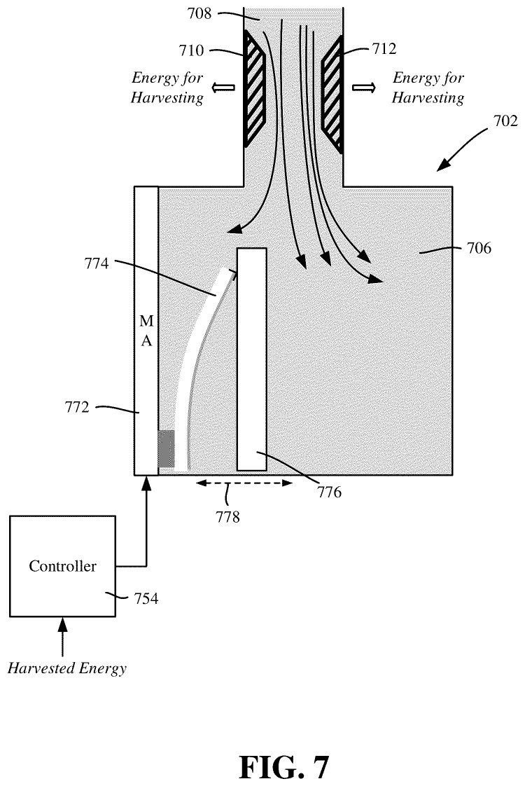

FIG. 7 shows the concept of a Helmholtz resonator 702 with variable resonance, which is based on a (e.g., bimorph) MEMS actuator (MA) 772, controlled by a controller 754, in which the controller 754 uses harvested energy as generated by transducers, including the transducers 710 and 712 of FIG. 7. As shown in FIG. 7, the example bimorph MEMS actuator (MA) 772 is in the form of a voltage-controlled bimorph cantilever 774, coupled to a moveable part 776 (e.g., a pillar) that is within the resonator's chamber 706, and thus is able to change the chamber's airflow based on the amount of displacement of the cantilever 774 and corresponding position of the moveable part 776. Note that the cantilever 774 itself can be positioned to change the airflow, with or without a pillar (not explicitly shown in FIG. 7), that is, the cantilever acts as the movable portion. Note that while the example bimorph MEMS actuator (MA) 722 is in the form of a cantilever 774 in FIG. 7, other types of MEMS actuators can be used instead, e.g., a lateral triple-arm device, and/or multiple MEMS actuators can work together to change the airflow.

In general, the bimorph MEMS actuator 772 changes the amount of cantilever displacement based on Joule heating, by applying a voltage across separated fixed (anchored) metallic ends of the cantilever 774, in which the metal (that is separated at the anchored end sides) is connected at the free end. The cantilever 774 thus can be in the shape of a penannular ring, U-shaped, V-shaped and so on, as long as voltage can be applied across the separated ends to heat the metal by current flow therethrough.

In the example of FIG. 7, the arrows through the neck port 708 represent some incoming airflow (the outgoing airflow is not explicitly represented, but is understood to be based on the resonator's resonant frequency). Thus, the airflow can be varied by control of the amount of MEMS cantilever displacement, from a largest amount of curvature (maximum pillar displacement), to a mostly flat angle (minimum pillar displacement). The dashed arrow 778 in FIG. 7 represents the range of the moveable part 776, based on the controlled amount of cantilever tip displacement, with respect to changing airflow.

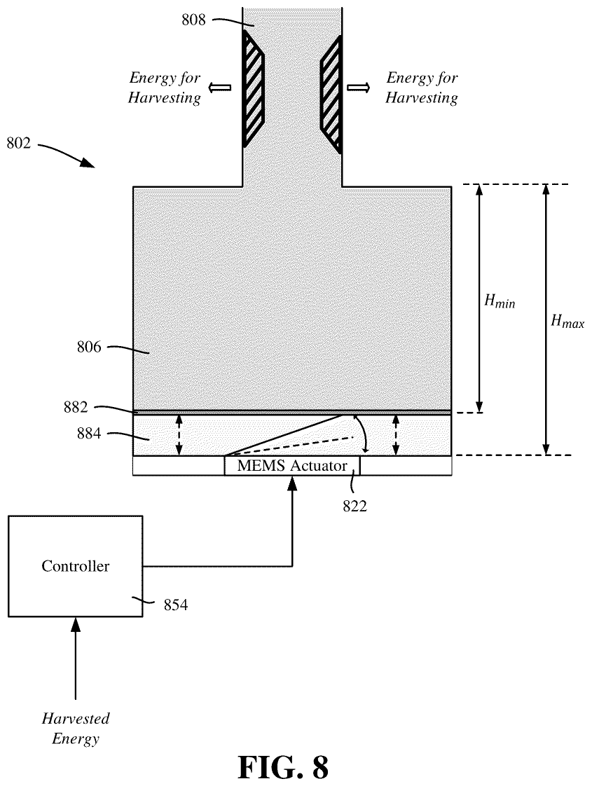

FIG. 8 shows the concept of a Helmholtz resonator 802 with variable resonance based on variable dimensions, which is based on a MEMS actuator (MA) 822, controlled by a controller 820, in which the controller 854 uses harvested energy as generated by transducers, including the transducers 810 and 812 of FIG. 8. As shown in FIG. 8, the example MEMS actuator (MA) 822 is in the form of a cantilever that is physically coupled to move a moveable partition (in this example, a floor 882 of the resonator 804), and thus is able to change the chamber's effective height between some minimum height Hmin and a maximum height Hmax, and thus vary the chamber's volume the (darker-shaded) chamber portion labeled 806. The dashed arrows in the lightly shaded area 884 in FIG. 8 represent the range of the moveable floor 882, based on the controlled amount of cantilever tip displacement, with respect to changing cavity volume.

Other types of MEMS actuators can be used instead, e.g., a lateral triple-arm device, and/or multiple MEMS actuators can work together to move a single partition. Note that a partition can be constructed as part of the MEMS device, e.g., a MEMS device can be fabricated along with the partition as a single unit.

In general, the MEMS actuator 822 changes the amount of cantilever displacement based on Joule heating, by applying a voltage across separated fixed (anchored) metallic ends of the cantilever, in which the metal (that is separated at the anchored end sides) is connected at the free end. The cantilever thus can be in the shape of a penannular ring, U-shaped, V-shaped and so on, as long as voltage can be applied across the separated ends to heat the metal by current flow therethrough.

In the example of FIG. 8, the chamber's variable volume with respect to resonating is the portion labeled 806, which can be varied by control of the amount of MEMS cantilever displacement. The volume of air in the (lightly-shaded) chamber portion labeled 884 (e.g., entering and exiting via one or more vents so that the air pressure is equalized) thus varies as well, but does not significantly affect the resonance of the Helmholtz resonator 802. A gasket or seal can be used if needed, however any slight change in the air pressure in the chamber portion 802 resulting from leaks around the moveable floor 882 likely can be compensated for by slightly adjusting the floor's height.

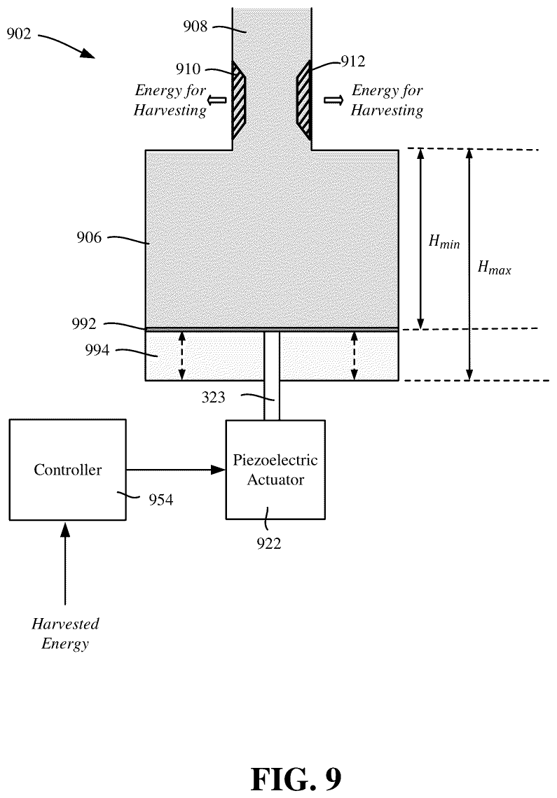

FIG. 9 shows a similar concept to that of FIG. 8, in which a moveable floor/piston 992 in the chamber 906 of a resonator 902 is moved by a piezoelectric actuator 922 (or similar motor) as controlled by a controller 954. The controlled amount of floor movement changes the dimensions of the resonator 902 and thus determines the resonant frequency. The controller 954 uses harvested energy as generated by transducers, including the transducers 910 and 912 of FIG. 9.

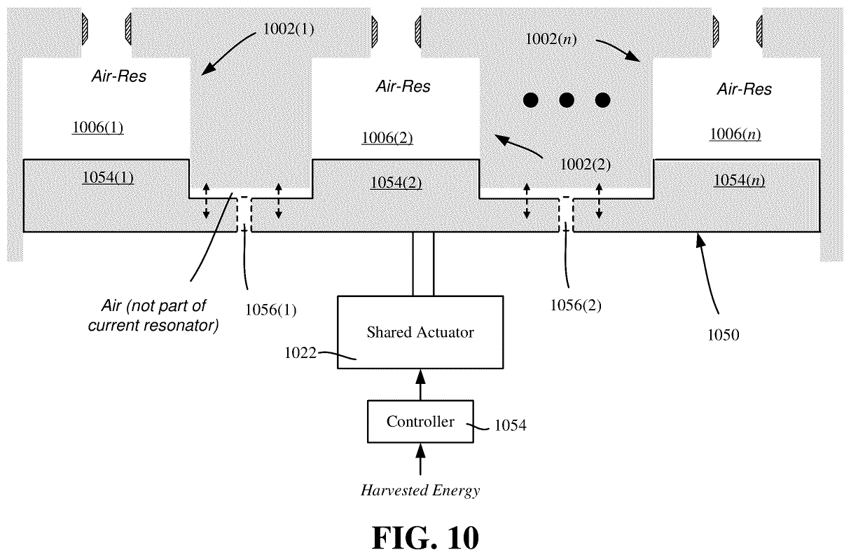

FIG. 10 shows a similar concept of resonator volume adjustment to that of FIGS. 8 and 9, except that in FIG. 10 a group of Helmholtz resonators 1002(1)-1002(n) have their respective volumes controlled by a shared tuning element, or actuator 1022, which in this example is controlled by a controller 1054 using the energy harvested by transducers (not individually labeled in FIG. 10). A shared moveable sheet 1050 with protrusions 1054(1)-1054(n) (e.g., cylindrical) form the respective movable floors of the resonators 1002(1)-1002(n). Vents 1056(1) and 1056(2) (two are shown, but others may be present) for air pressure equalization facilitate movement of the moveable sheet 1050 by the shared actuator (tuning element) 1022. As can be seen in FIG. 10, the volumes of the chambers 1006(1)-1006(n) are reduced by moving the moveable sheet 1050 upwards, and increased by moving the moveable sheet 1050 downwards thereby changing the resonance frequency of the resonators 1002(a)-1002(n).

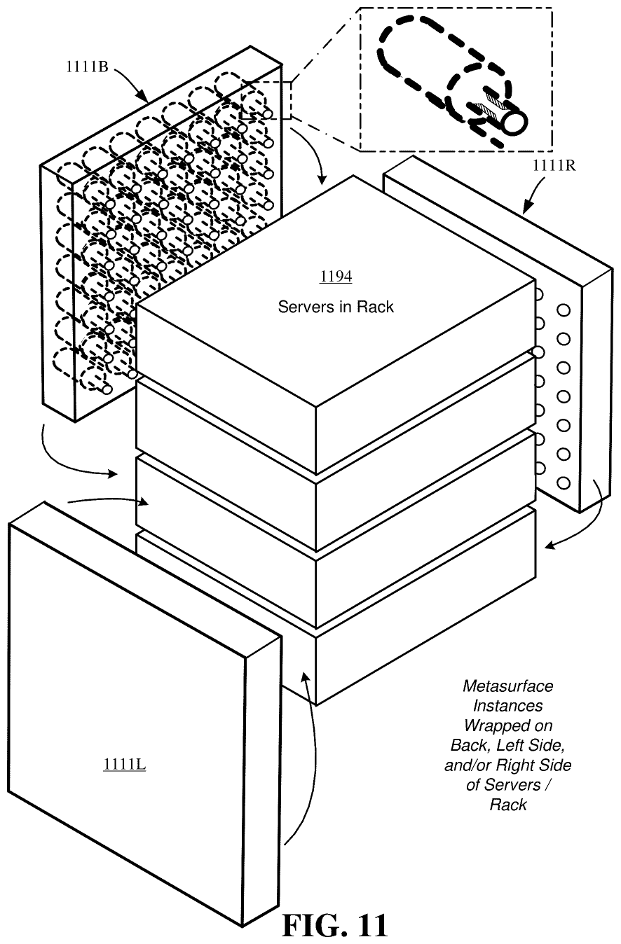

Some or all of the sound absorbing unit cells can be fabricated using 3D printing technology with the features of material simplicity and deeply sub-wavelength compact design. FIG. 11 depicts an example usage scenario, in which multiple metasurfaces 1111B, 1111L and 1111R as described herein can be positioned as a noise canceling device proximate a rack of servers 1194. As shown in the enlarged portion of the metasurface 1111B, the unit cell resonators have transducers attached in or near their neck ports.

A piezo transducer or membrane-type transducer can be at the neck of the resonator. The placement of energy harvesting devices can be carefully chosen, e.g., a field distribution of the designed resonator is first simulated and based on the simulation, the highest pressure areas are selected for transducer placement. Trained models can provide insights or analytics about the placement of such transducers, because a machine learning model can provide design specifications of the resonators, along with data about the location of maximum acoustic pressure.

One or more aspects can be embodied in a system, such as described and represented in the drawing figures herein. The system can include a unit cell of a metasurface configured for sound absorption of an incoming acoustic wave within a narrowband frequency range. The unit cell can include a resonator including an air cavity within supporting material. The resonator can include a chamber and a neck port that exposes the air cavity to the incoming acoustic wave. The system further can include a membrane-based transducer coupled to the resonator, the membrane-based transducer configured to oscillate based on force from acoustic pressure of the incoming acoustic wave, responsive to the unit cell being exposed to the incoming acoustic wave, to electricity that can be harvested as energy.

The membrane-based transducer can include a cymbal harvester transducer. The cymbal harvester transducer can include piezoelectric material coated on the supporting material proximate to the air cavity.

The system further can include including an energy storage device electrically coupled to the membrane-based transducer to obtain and store the energy. The system further can include a resonant frequency reconfiguration device electrically coupled to draw current from the energy storage device to adjust a resonant frequency of the resonator, to resonate the resonator at the resonant frequency to phase cancel the incoming acoustic wave, responsive to the unit cell being exposed to the incoming acoustic wave.

The system further can include a heater electrically coupled to the membrane-based transducer to convert at least some of the energy to heat, to heat air in the resonator as part of determining a resonant frequency of the resonator, to resonate the resonator at the resonant frequency to phase cancel the incoming acoustic wave, responsive to the unit cell being exposed to the incoming acoustic wave.

The resonator can include a moveable partition that can be moveable to change a volume of the resonator, and the system further can include an actuator electrically coupled to the membrane-based transducer to move the moveable partition, using at least some of the energy, to change the volume of the resonator as part of determining a resonant frequency of the resonator, to resonate the resonator at the resonant frequency to phase cancel the incoming acoustic wave, responsive to the unit cell being exposed to the incoming acoustic wave.

The resonator can include a device including a moveable portion that can be moveable to change airflow in the resonator; the device can be coupled to the membrane-based transducer to move the moveable portion, using at least some of the energy, to change the airflow of the resonator as part of determining a resonant frequency of the resonator, to resonate the resonator at the resonant frequency to phase cancel the incoming acoustic wave, responsive to the unit cell being exposed to the incoming acoustic wave.

The membrane-based transducer can be a first cymbal harvester transducer, the electricity can be first electricity harvested as first energy, and the system further can include a second cymbal harvester transducer configured to oscillate based on the force from the acoustic pressure of the incoming acoustic wave, responsive to the unit cell being exposed to the incoming acoustic wave, to second electricity that can be harvested as second energy. The first cymbal harvester transducer can include first piezoelectric material coated on a first part of the supporting material positioned proximate to a first side of the neck cavity, and the second cymbal harvester transducer can include second piezoelectric material coated on a second part of the supporting material positioned proximate to a second side of the neck cavity.

One or more aspects can be embodied in an acoustic metasurface, such as described and represented in the drawing figures herein. The acoustic metasurface can include air cavity resonators within supporting material. Cymbal harvester transducers can be coupled to at least some of the air cavity resonators; the cymbal harvester transducers produce electricity to be harvested as energy based on acoustic waves entering the air cavity resonators.

The air cavity resonators can be configured to resonate at a resonance frequency corresponding to the acoustic waves, to phase cancel at least some noise corresponding to the acoustic waves, and the cymbal harvester transducers can be configured to oscillate at the resonance frequency.

The acoustic metasurface can be deployed proximate to a server to phase cancel the at least some noise corresponding to the acoustic waves emanating from a server.

The air cavity resonators can include neck ports and chambers, and the cymbal harvester transducers coupled to at least some of the air cavity resonators can be coupled proximate to at least some of the neck ports.

The acoustic metasurface can be formed by a three-dimensional printer that prints the supporting material as a solid structure in layers, in conjunction with omitting printing of the air cavity resonators.

One or more aspects can be embodied in a system, such as described and represented in the drawing figures herein. The system can include an acoustic metasurface including unit cell resonators, the unit cell resonators including respective air cavities within a supporting structure of the acoustic metasurface, the respective air cavities including respective openings in the supporting structure. Cymbal harvester transducers can be coupled to at least some of the unit cell resonators to harvest energy based on acoustic pressure of an acoustic wave entering the respective air cavities via the respective openings. The system further can include an energy storage device coupled to the cymbal harvester transducers to store at least some of the energy.

The system further can include a resonant frequency reconfiguration device coupled to the energy storage device configured to change the resonant frequency of the unit cells resonators based on energy drawn by the resonant frequency reconfiguration device from the energy storage device. The resonant frequency reconfiguration device can include at least one of: a heater configured to change the resonant frequency of the unit cells resonators by changing respective temperatures of the respective air cavities, a first actuator configured to change the resonant frequency of the unit cells resonators by changing respective dimensions of the respective air cavities, or a second actuator configured to change the resonant frequency of the unit cells resonators by changing respective airflow in the respective air cavities.

The system further can include a controller and a sensor, the controller can be coupled to the sensor, and the controller can be coupled to control operation of the resonant frequency reconfiguration device based on data obtained by the controller from the sensor.

The cymbal harvester transducers can be coupled to the at least some of the unit cell resonators proximate to respective areas of the respective air cavities that can be respective higher acoustic pressure areas relative to lower acoustic pressure areas of the respective air cavities.

As can be seen, the technology described herein facilitates construction and deployment of acoustic unit cells having transducers from which energy can be harvested. The harvested energy can be used to adjust the resonant frequency of the unit cells, such as by integrating flexible heaters inside the cavity heated by the energy generated from the piezoelectric transducer, which can be directly or indirectly (via an energy storage) applied to drive the heating mechanism. A linear motor mechanism can be similarly driven by the harvested energy.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A system, comprising:
a unit cell of a metasurface configured for sound absorption of an incoming acoustic wave within a narrowband frequency range, the unit cell comprising a resonator comprising an air cavity within supporting material, the resonator comprising a chamber and a neck port that exposes the air cavity to the incoming acoustic wave; and
a membrane-based transducer coupled to the resonator, the membrane-based transducer configured to oscillate based on force from acoustic pressure of the incoming acoustic wave, responsive to the unit cell being exposed to the incoming acoustic wave, to electricity that is harvested as energy.

2. The system of claim 1, wherein the membrane-based transducer comprises a cymbal harvester transducer.

3. The system of claim 2, wherein the cymbal harvester transducer comprises piezoelectric material coated on the supporting material proximate to the air cavity.

4. The system of claim 1, further comprising an energy storage device electrically coupled to the membrane-based transducer to obtain and store the energy.

5. The system of claim 4, further comprising a resonant frequency reconfiguration device electrically coupled to draw current from the energy storage device to adjust a resonant frequency of the resonator, to resonate the resonator at the resonant frequency to phase cancel the incoming acoustic wave, responsive to the unit cell being exposed to the incoming acoustic wave.

6. The system of claim 1, further comprising a heater electrically coupled to the membrane-based transducer to convert at least some of the energy to heat, to heat air in the resonator as part of determining a resonant frequency of the resonator, to resonate the resonator at the resonant frequency to phase cancel the incoming acoustic wave, responsive to the unit cell being exposed to the incoming acoustic wave.

7. The system of claim 1, wherein the resonator comprises a moveable partition that is moveable to change a volume of the resonator, and further comprising an actuator electrically coupled to the membrane-based transducer to move the moveable partition, using at least some of the energy, to change the volume of the resonator as part of determining a resonant frequency of the resonator, to resonate the resonator at the resonant frequency to phase cancel the incoming acoustic wave, responsive to the unit cell being exposed to the incoming acoustic wave.

8. The system of claim 1, wherein the resonator comprises a device comprising a moveable portion that is moveable to change airflow in the resonator, the device coupled to the membrane-based transducer to move the moveable portion, using at least some of the energy, to change the airflow of the resonator as part of determining a resonant frequency of the resonator, to resonate the resonator at the resonant frequency to phase cancel the incoming acoustic wave, responsive to the unit cell being exposed to the incoming acoustic wave.

9. The system of claim 1, wherein the membrane-based transducer is a first cymbal harvester transducer, wherein the electricity is first electricity harvested as first energy, and further comprising a second cymbal harvester transducer configured to oscillate based on the force from the acoustic pressure of the incoming acoustic wave, responsive to the unit cell being exposed to the incoming acoustic wave, to second electricity that is harvested as second energy.

10. The system of claim 9, wherein the first cymbal harvester transducer comprises first piezoelectric material coated on a first part of the supporting material positioned proximate to a first side of the neck cavity, and wherein the second cymbal harvester transducer comprises second piezoelectric material coated on a second part of the supporting material positioned proximate to a second side of the neck cavity.

11. An acoustic metasurface, comprising:
air cavity resonators within supporting material; and
cymbal harvester transducers coupled to at least some of the air cavity resonators, wherein the cymbal harvester transducers produce electricity to be harvested as energy based on acoustic waves entering the air cavity resonators.

12. The acoustic metasurface of claim 11, wherein the air cavity resonators are configured to resonate at a resonance frequency corresponding to the acoustic waves, to phase cancel at least some noise corresponding to the acoustic waves, and wherein the cymbal harvester transducers are configured to oscillate at the resonance frequency.

13. The acoustic metasurface of claim 12, wherein the acoustic metasurface is deployed proximate to a server to phase cancel the at least some noise corresponding to the acoustic waves emanating from a server.

14. The acoustic metasurface of claim 11, wherein the air cavity resonators comprise neck ports and chambers, and wherein the cymbal harvester transducers coupled to at least some of the air cavity resonators are coupled proximate to at least some of the neck ports.

15. The acoustic metasurface of claim 11, wherein the acoustic metasurface is formed by a three-dimensional printer that prints the supporting material as a solid structure in layers, in conjunction with omitting printing of the air cavity resonators.

16. A system, comprising:
an acoustic metasurface comprising unit cell resonators, the unit cell resonators comprising respective air cavities within a supporting structure of the acoustic metasurface, the respective air cavities comprising respective openings in the supporting structure;
cymbal harvester transducers coupled to at least some of the unit cell resonators to harvest energy based on acoustic pressure of an acoustic wave entering the respective air cavities via the respective openings; and
an energy storage device coupled to the cymbal harvester transducers to store at least some of the energy.

17. The system of claim 16, further comprising a resonant frequency reconfiguration device coupled to the energy storage device configured to change the resonant frequency of the unit cells resonators based on energy drawn by the resonant frequency reconfiguration device from the energy storage device.

18. The system of claim 17, wherein the resonant frequency reconfiguration device comprises at least one of: a heater configured to change the resonant frequency of the unit cells resonators by changing respective temperatures of the respective air cavities, a first actuator configured to change the resonant frequency of the unit cells resonators by changing respective dimensions of the respective air cavities, or a second actuator configured to change the resonant frequency of the unit cells resonators by changing respective airflow in the respective air cavities.

19. The system of claim 17, further comprising a controller and a sensor, wherein the controller is coupled to the sensor, and wherein the controller is coupled to control operation of the resonant frequency reconfiguration device based on data obtained by the controller from the sensor.

20. The system of claim 16. wherein the cymbal harvester transducers are coupled to the at least some of the unit cell resonators proximate to respective areas of the respective air cavities that are respective higher acoustic pressure areas relative to lower acoustic pressure areas of the respective air cavities.
